(19) United States
(12) Patent Application Publication
(10) Pub. No.: US 2025/0351419 A1
(43) Pub. Date: Nov. 13, 2025

(54) SEMICONDUCTOR DEVICE WITH HYBRID SUBSTRATE AND MANUFACTURING METHODS THEREOF

(71) Applicant: Taiwan Semiconductor Manufacturing Company, Ltd., Hsin-Chu (TW)

(72) Inventors: Wei-Lun Min, Nantou County (TW); Chang-Miao Liu, Hsinchu City (TW); Huiling Shang, Hsinchu County (TW)

(21) Appl. No.: 19/276,912

(22) Filed: Jul. 22, 2025

Related U.S. Application Data
(63) Continuation of application No. 18/407,524, filed on Jan. 9, 2024.
(60) Provisional application No. 63/520,688, filed on Aug. 21, 2023.

(51) Int. Cl. H10D 30/62; H10D 30/01; H10D 30/67; H10D 62/13; H10D 64/01

(52) U.S. Cl. CPC H10D 30/62; H10D 30/024; H10D 30/6735; H10D 30/6757; H10D 62/151; H10D 64/017

(57) ABSTRACT

The present disclosure provides a semiconductor device and a method of forming the same. The semiconductor device includes a fin-shape base protruding from a semiconductor substrate. A top surface of the semiconductor substrate is in a (100) crystal plane, and a top surface of the fin-shape base is in a (110) crystal plane. The semiconductor device also includes channel members disposed over the top surface of the fin-shape base, a gate structure wrapping around at least one of channel members, a gate spacer extending along a sidewall of the gate structure, a source/drain feature abutting the channel members, and a dopant-free epitaxial feature under the source/drain feature. A top surface of the source/drain feature is in a (110) crystal plane. A top surface of the dopant-free epitaxial feature is in a (110) crystal plane.

### PRIORITY DATA

This is a continuation application of U.S. patent application Ser. No. 18/407,524, filed Jan. 9, 2024, which claims the benefits of U.S. Provisional Patent Application No. 63/520,688, filed Aug. 21, 2023, each of which is incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as IC technologies progress towards smaller nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor.

To improve performance of an MBC transistor, efforts are invested to develop features and structures in source/drain regions that strain channels and suppress substrate current leakage. While conventional features and structures in source/drain regions are generally adequate to their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIG. 2 illustrates a perspective view of a workpiece during a bonding process according to the method of FIG. 1, according to one or more aspects of the present disclosure.

FIGS. 3, 4, 5, 6, 7, 8, 9, 10, 11, 12, 13, 14, 15, 16, 17, 18, 19, 20, 21, 22, 23, 24, 25, and 26 illustrate fragmentary cross-sectional views of a workpiece during a fabrication process according to the method of FIG. 1, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure is generally related to multi-gate transistors and fabrication methods, and more particularly to multilayer features developed in source/drain regions of MBC transistors. Channel regions of an MBC transistor may be disposed in nanowire channel members, bar-shaped channel members, nanosheet channel members, nanostructure channel members, column-shaped channel members, post-shaped channel members, and/or other suitable channel configurations. Depending on the shapes of the channel members, MBC transistors may also be referred to as nano wire transistors or nanosheet transistors. Despite of the shapes, each of the channel members of an MBC transistor extend between and are coupled to two epitaxial features formed in source/drain regions (also referred to as source/drain epitaxial features or source/drain features). Source/drain region(s) may refer to a source or a drain, individually or collectively dependent upon the context. Ideal source/drain features of an MBC transistor introduce strain on the channel members and provide low resistance. During the formation of the MBC transistor, inserting a dielectric film that separates bottom surfaces of source/drain features may help isolating the source/drain features from the substrate and thus suppress leakage current into the substrate. Although such a dielectric film is helpful to boost AC performance, it may deteriorate DC performance in p-type transistors with an increased resistance. The deterioration of DC performance in p-type transistors may be due to a loss of compressive strain.

The present disclosure provides embodiments of a semiconductor device with a hybrid substrate. The hybrid substrate provides a (100) crystal plane in an NFET region (where n-type transistors are formed) and a (110) crystal plane in an PFET region (where p-type transistors are formed). Epitaxial stacks comprising channel layers for n-type transistors and p-type transistors are epitaxially grown from the (100) crystal plane and the (110) crystal plane, respectively. The channel layers inherit the crystal orientations from the hybrid substrate, resulting in high mobility channel in not just n-type transistors but also p-type transistors. Not just channel layers, source/drain features epitaxially grown from end portions of the respective channel layers also inherit the crystal orientations of the hybrid substrate from the respective channel layers. The (110) source/drain features in the p-type transistors mitigate the loss of compressive strain due to the insertion of the dielectric film underneath the respective source/drain features. Therefore, AC and DC performances of transistors in NFET and PFET regions are both optimized without sacrificing DC performance of transistors in the PFET region. Further, a base epitaxial layer may optionally be formed between the substrate and the dielectric film. The base epitaxial layer may be undoped to increase its resistance, which further improves the suppression of leakage current from the source/drain features into the substrate.

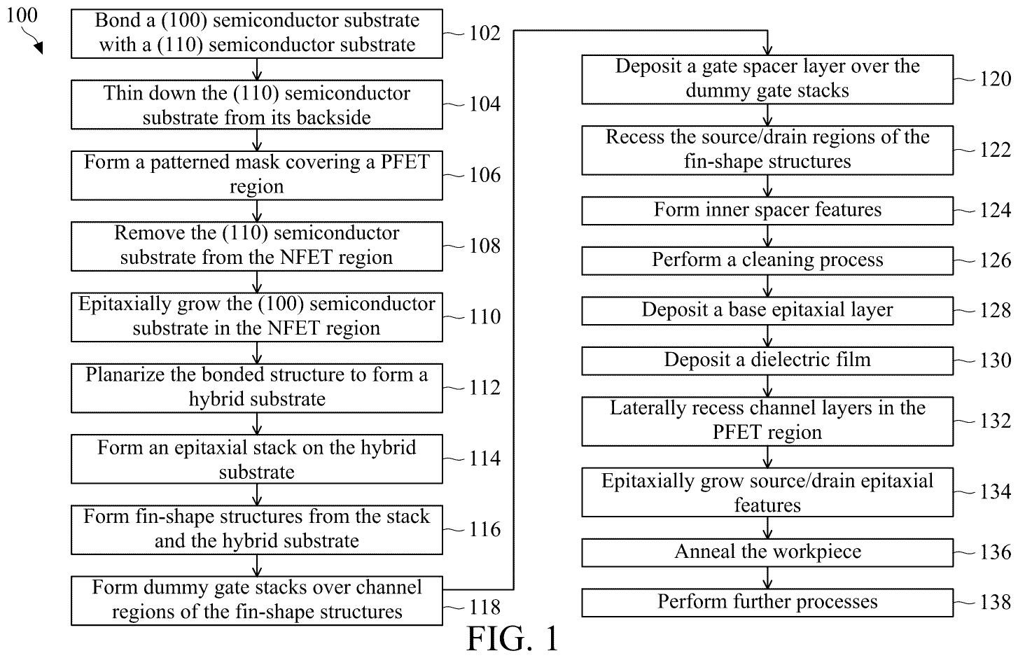

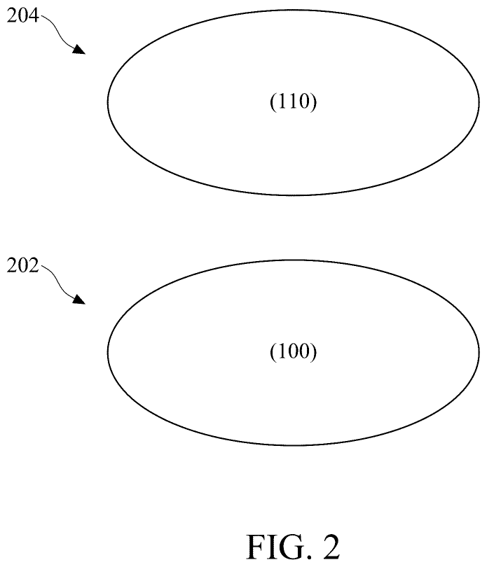

The various aspects of the present disclosure will now be described in more detail with reference to the figures. In that regard, FIG. 1 is a flowchart illustrating a method 100 of forming a semiconductor device from a workpiece according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIGS. 2-26, which are perspective and fragmentary cross-sectional views of workpiece 200 at different stages of fabrication according to embodiments of the method 100 in FIG. 1. Because the workpiece 200 will be fabricated into a semiconductor device, the workpiece 200 may be referred to herein as a semiconductor device 200 as the context requires. For avoidance, the X, Y and Z directions in FIGS. 2-26 are perpendicular to one another. Throughout the present disclosure, like reference numerals denote like features, unless otherwise excepted.

Referring to FIG. 1 and FIGS. 2-3, method 100 includes a block 102 where a first semiconductor substrate 202 and a second semiconductor substrate 204 are bonded together to form the workpiece 200. In some embodiments, the first semiconductor substrate 202 is a first wafer, such as a first silicon wafer, and the second semiconductor substrate 204 is a second wafer, such as a second silicon wafer. The first semiconductor substrate 202 and the second semiconductor substrate 204 have different crystal plane orientations.

In crystalline semiconductor materials, the atoms which make up the solid are arranged in a periodic fashion. If the periodic arrangement exists throughout the solid, the substance is defined as being formed of a crystal. The periodic arrangement of atoms in a crystal is commonly called “the crystal lattice.” The crystal lattice also contains a volume which is representative of the entire lattice and is referred to as a unit cell that is regularly repeated throughout the crystal. For example, silicon has a diamond cubic lattice structure, which can be represented as two interpenetrating face-centered cubic lattices. Thus, the simplicity of analyzing and visualizing cubic lattices can be extended to the characterization of silicon crystals. In the description herein, references to various planes in semiconductor crystals (e.g., silicon crystals) will be made, especially to the (100), (110), and (111) crystal planes. These planes define the orientation of the plane of semiconductor atoms relative to the principle crystalline axes. The numbers (xyz) are referred to as Miller indices and are determined from the reciprocals of the points at which the crystal plane of silicon intersects the principal crystalline axes.

For example, in the illustrated embodiment, the first semiconductor substrate 202 may have a top surface in a (100) crystal plane and the second semiconductor substrate 204 may have a top surface in a (110) crystal plane. The first semiconductor substrate 202 is also referred to as a (100) semiconductor substrate or a semiconductor substrate having (100) orientation. The second semiconductor substrate 204 is also referred to as a (110) semiconductor substrate or a semiconductor substrate having (110) orientation. In some embodiments, the two semiconductor substrates 202 and 204 are silicon substrates (e.g., silicon wafers). However, the disclosed structure and the method are not limiting and are extendable to other suitable semiconductor substrates and other suitable crystal orientations. For examples, either of the semiconductor substrates 202 and 204 may include an elementary semiconductor, such as germanium; a compound semiconductor, such as silicon germanium, silicon carbide, gallium arsenic, gallium phosphide, indium phosphide, indium arsenide, and/or indium antimonide; or combinations thereof, in the same or different crystalline structures.

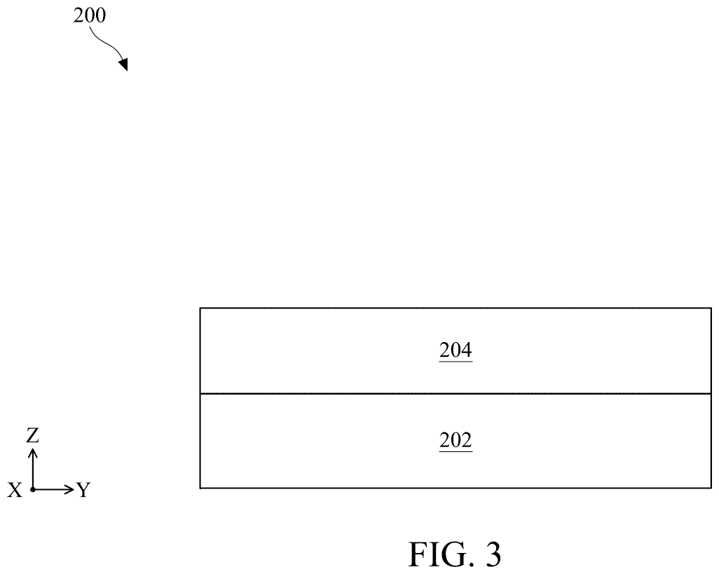

The example of FIGS. 2 and 3 illustrates the two semiconductor substrates 202 and 204 are bonded together with such configuration through a proper bonding technology, such as direct bonding, eutectic bonding, fusion bonding, diffusion bonding, anodic bonding or other suitable bonding method. In one embodiment, the semiconductor substrates are bonded together by direct silicon bonding (DSB). For example, the direct silicon bonding process may include preprocessing, pre-bonding at a lower temperature, and annealing at a higher temperature. A buried silicon oxide layer (BOX), or referred to as silicon oxide layer, may be implemented therebetween when the two substrates are bonded together.

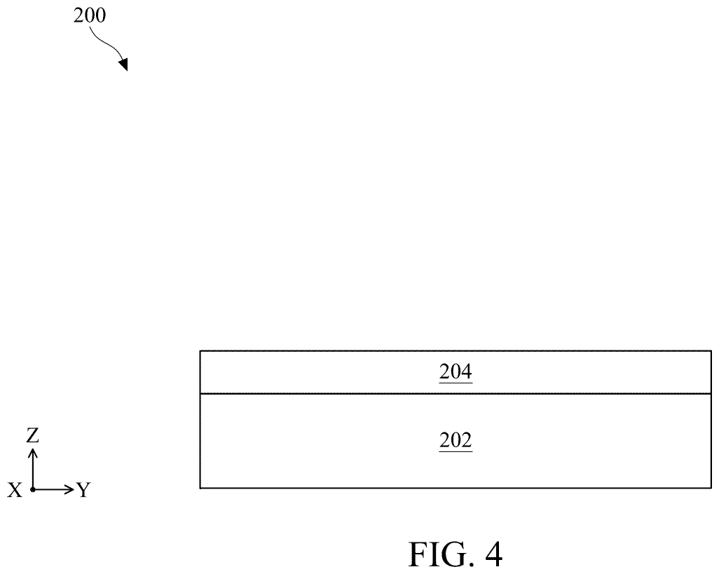

Referring to FIGS. 1 and 4, method 100 includes a block 104 where the semiconductor substrates 204 is thinned down. In some embodiments, a thinning process is applied to thin down the semiconductor substrate 204 from its backside surface. The thinning process may include a mechanical grinding process and a chemical thinning process. A substantial amount of substrate material may be first removed from the semiconductor substrate 204 during the mechanical grinding process. Afterwards, the chemical thinning process may apply an etching chemical to the back side of the semiconductor substrate 204 to further thin the semiconductor substrate 204 to a proper thickness. The thickness affects the crystal quality of the epitaxial layers subsequently formed on the workpiece 200. In some embodiments, the thickness of the semiconductor substrate 204 is in a range from about 30 nm to about 100 nm.

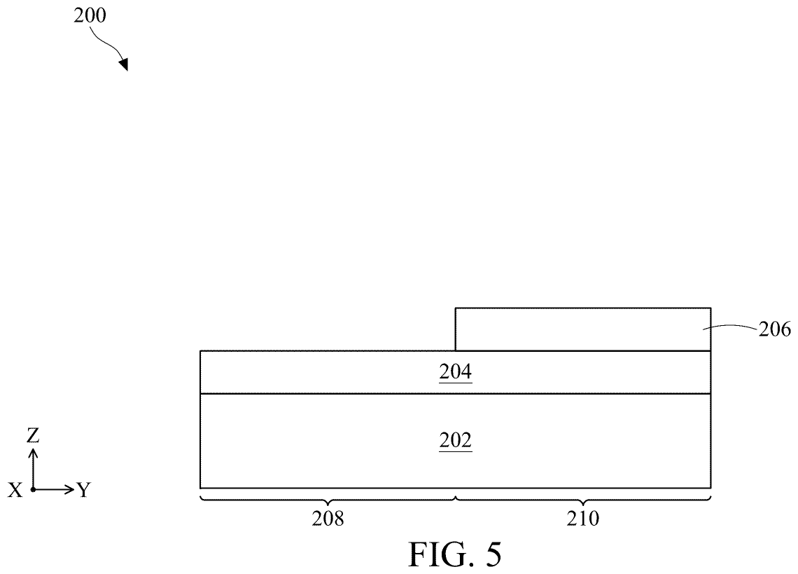

Referring to FIGS. 1 and 5, method 100 includes a block 106 where a patterned mask 206 is formed on the top surface of the workpiece 200. The patterned mask 206 includes an opening that exposes a first region 208 of the workpiece 200 and covers a second region 210 of the workpiece 200. The first region 208 is a region of the workpiece 200 defined for one or more n-type field effect transistor(s) (FET) and the second region 210 is a region of the workpiece 200 defined for one or more p-type FET(s). The first region 208 is also referred to as the NFET region 208, and the second region 210 is also referred to as the PFET region 210 in the context. The patterned mask 206 may be a soft mask such as a patterned resist layer, or a hard mask such as a dielectric material layer, or a combination thereof. In one embodiment, the patterned mask 206 is a hard mask with a patterned resist layer (not shown) formed on the hard mask by a lithography process. The hard mask is etched to transfer the opening from the patterned resist layer to the hard mask. In some examples, the hard mask includes silicon oxide, silicon nitride, silicon oxynitride, silicon carbide, silicon carbide nitride, silicon carbide oxynitride, other semiconductor material, and/or other dielectric material. In an embodiment, the hard mask has a thickness ranging from about 1 nm to about 40 nm. The hard mask may be formed by thermal oxidation, chemical vapor deposition (CVD), atomic layer deposition (ALD), or any other appropriate method. An exemplary photolithography process may include forming a resist layer, exposing the resist by a lithography exposure process, performing a post-exposure bake process, and developing the photoresist layer to form the patterned photoresist layer. The lithography process may be alternatively replaced by other technique, such as e-beam writing, ion-beam writing, maskless patterning or molecular printing. In some embodiments, the patterned resist layer may be directly used as an etch mask for the subsequent etch process. The patterned resist layer may be removed by a suitable process, such as wet stripping or plasma ashing, after the patterning of the hard mask.

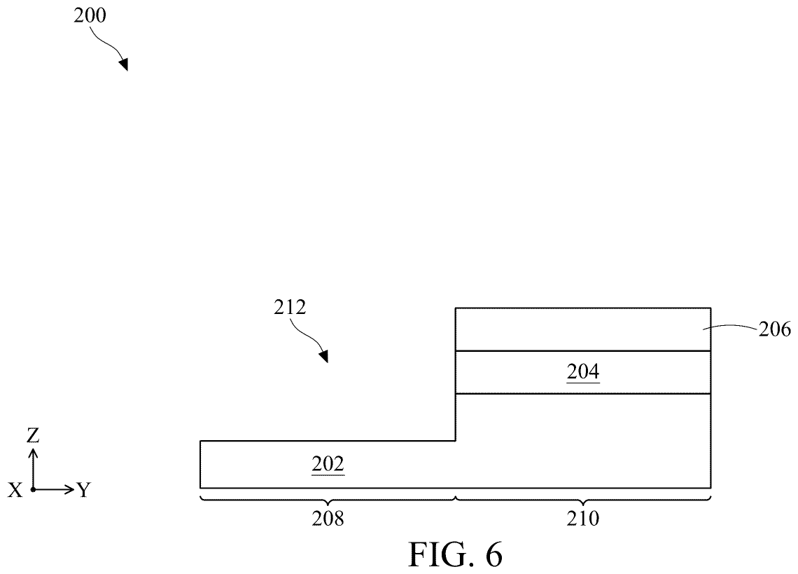

Referring to FIGS. 1 and 6, method 100 includes a block 108 where an etching process is performed through the opening defined in the patterned mask 206. The etching process removes the semiconductor substrate 204 from the NFET region 208 until the semiconductor substrate 202 is exposed, resulting in a recess 212. The etching process uses the patterned mask 206 as an etch mask. The etching process may further continue to recess the semiconductor substrate 202 such that a top surface of the semiconductor substrate 202 is below a bottom surface of the semiconductor substrate 204. A sidewall of the semiconductor substrate 204 is also exposed defining an edge of the recess 212. The etching process may include dry etch, wet etch, or a combination thereof. The patterned mask 206 protects the semiconductor substrate 204 within the PFET region 210 from etching. In various examples, the etching process may include a dry etch with a suitable etchant, such as fluorine-containing etching gas or chlorine-containing etching gas, such as Cl₂, CCl₂F₂, CF₄, SF₆, NF₃, CH₂F₂ or other suitable etching gas. In some other examples, the etching process may include a wet etch with a suitable etchant, such as a hydrofluoric acid (HF) based solution, a sulfuric acid (H₂SO₄) based solution, a hydrochloric (HCl) acid based solution, an ammonium hydroxide (NH₄OH) based solution, other suitable etching solution, or combinations thereof. The etching process may include more than one step.

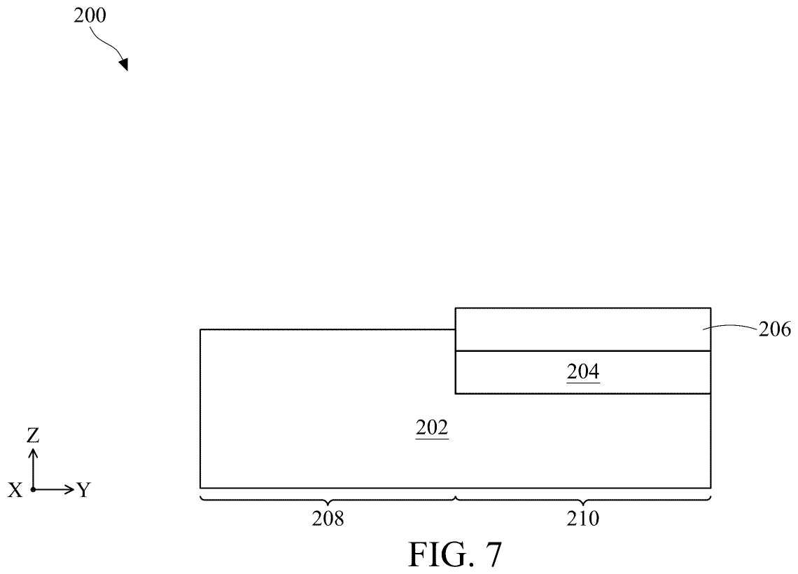

Referring to FIGS. 1 and 7, method 100 includes a block 110 where epitaxial growth is performed to grow a thickness of the semiconductor substrate 202 in the NFET region 208. In an example that the semiconductor substrate 202 is a silicon wafer, crystalline silicon is epitaxial grown in the recess 212 and carries the crystalline structure of the semiconductor substrate 202. That is, the top surface of the epitaxially grown crystalline silicon has a (100) crystal plane. In the illustrated embodiment, the elevated top surface of the semiconductor substrate 202 is above the top surface of the semiconductor substrate 204 and intersects a sidewall of the patterned mask 206. The crystalline silicon may be grown by a molecular beam epitaxy (MBE) process, a chemical vapor deposition (CVD) process such as a metal organic CVD (MOCVD) process, and/or other suitable epitaxial growth processes. The patterned mask 206 prevents the epitaxial growth from taking place in the PFET region 210. At the conclusion of the epitaxial growth, the top surface of the semiconductor substrate 202 may be higher than the top surface of the semiconductor substrate 204 for a range from about 30 nm to about 100 nm.

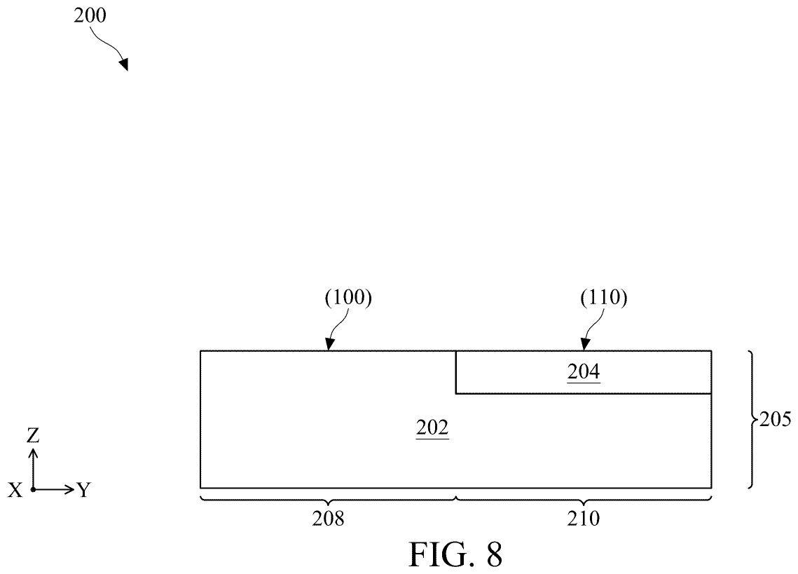

Referring to FIGS. 1 and 8, method 100 includes a block 112 where a planarization process, such as a chemical mechanical polishing (CMP) process is performed to planarize the top surface of the workpiece 200. The patterned mask 206 may be used as a polishing stop layer during the CMP process and is removed by etching after the CMP. Alternatively, the patterned mask 206 may be removed by the CMP process. After the CMP process, the top surfaces of the semiconductor substrates 202 and 204 are both exposed and substantially coplanar. The remaining thickness of the semiconductor substrate 204 is in a range from about 30 nm to about 100 nm. As the elevated portion of the semiconductor substrate 202 is formed by epitaxial growth from the (100) crystal plane, it is in the crystalline structure and carries the same crystal orientation. That is, the top surface of the semiconductor substrate 202 in the NFET region 208 is still in the (100) crystal plane, while the top surface of the semiconductor substrate 204 within the PFET region 210 is in the (110) crystal plane. At the conclusion of the block 112, the semiconductor substrate 202 and the semiconductor substrate 204 (also referred to as semiconductor layer 204) collectively define a hybrid substrate 205.

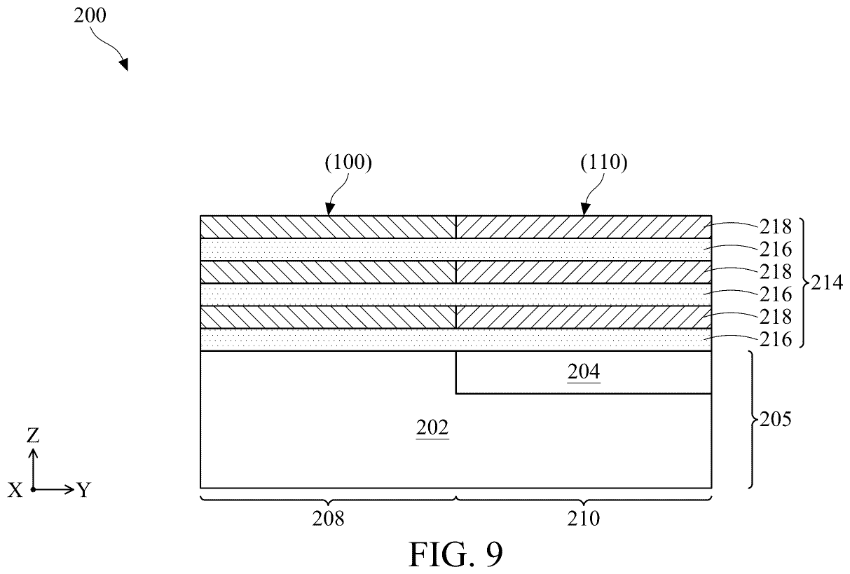

Referring to FIGS. 1 and 9, method 100 includes a block 114 where a stack 214 of alternating semiconductor layers is formed over the hybrid substrate 205. In some embodiments, prior to the forming of the stack 214, the NFET region 208 and the PFET region 210 are doped with respective doping profiles depending on design requirements as is known in the art. For example, p-type dopant(s) may be doped into the NFET region 208 to form p-type well (or p-well), and n-type dopant(s) may be doped into the PFET region 210 to form n-type well (or n-well). The n-type dopant for forming the n-type well may include phosphorus (P) or arsenic (As). The p-type dopant for forming the p-type well may include boron (B) or gallium (Ga). The suitable doping may include ion implantation of dopants and/or diffusion processes. After the dopant implantation, the stack 214 is epitaxially grown over the hybrid substrate 205.

In some embodiments, the stack 214 includes sacrificial layers 216 of a first semiconductor composition interleaved by channel layers 218 of a second semiconductor composition. The first and second semiconductor composition may be different. In some embodiments, the sacrificial layers 216 include silicon germanium (SiGe) and the channel layers 218 include silicon (Si). It is noted that three (3) layers of the sacrificial layers 216 and three (3) layers of the channel layers 218 are alternately arranged as illustrated in FIG. 9, which is for illustrative purposes only and not intended to be limiting beyond what is specifically recited in the claims. It can be appreciated that any number of epitaxial layers may be formed in the stack 214. The number of layers depends on the desired number of channels members for the workpiece 200. In some embodiments, the number of channel layers 218 is between 1 and 20.

In some embodiments, all sacrificial layers 216 may have a substantially uniform first thickness between about 3 nm and about 10 nm and all of the channel layers 218 may have a substantially uniform second thickness between about 3 nm and about 15 nm. The first thickness and the second thickness may be the same or different. As described in more detail below, the channel layers 218 or parts thereof may serve as channel member(s) for a subsequently-formed multi-gate device and the thickness of each of the channel layers 218 is chosen based on device performance considerations. The sacrificial layers 216 in channel regions(s) may eventually be removed and serve to define a vertical distance between adjacent channel region(s) for a subsequently-formed multi-gate device and the thickness of each of the sacrificial layers 216 is chosen based on device performance considerations.

The layers in the stack 214 may be deposited using a molecular beam epitaxy (MBE) process, a vapor phase deposition (VPE) process, and/or other suitable epitaxial growth processes. Therefore, the stack 214 is also referred to as the epitaxial stack 214. As stated above, in at least some examples, the sacrificial layers 216 include an epitaxially grown silicon germanium (SiGe) layer and the channel layers 218 include an epitaxially grown silicon (Si) layer. In some embodiments, the sacrificial layers 216 and the channel layers 218 are substantially dopant-free (i.e., having an extrinsic dopant concentration from about 0 cm⁻³ to about 1×10¹⁷ cm⁻³), where for example, no intentional doping is performed during the epitaxial growth processes for the stack 214. In the NFET region 208, the top surface of the semiconductor substrate 202 is in a (100) crystal plane, and accordingly each layer of the stack 214 in the NFET region 208 has a (100) top surface. In the PFET region 210, the top surface of the semiconductor layer 204 is in a (110) crystal plane, and accordingly each layer of the stack 214 in the PFET region 210 has a (110) top surface.

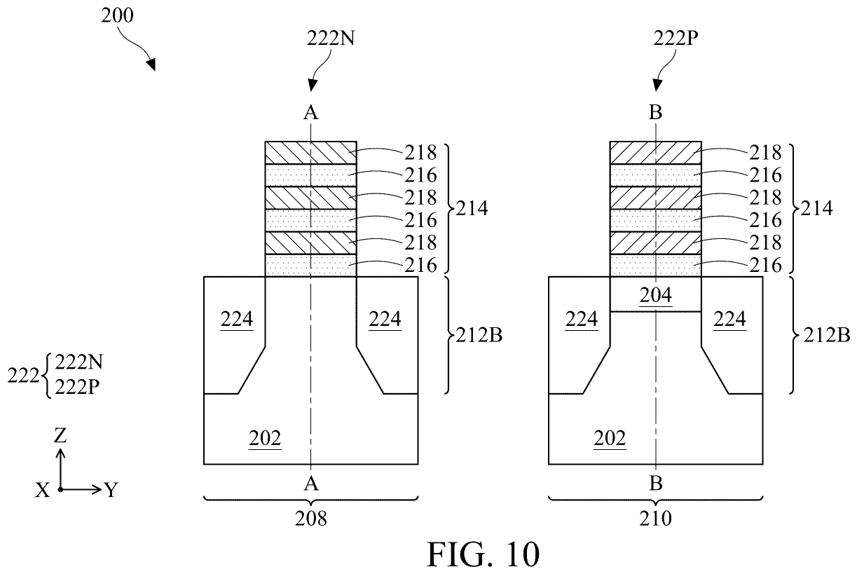

Referring to FIGS. 1 and 10, method 100 includes a block 116 where fin-shape structures 222 are formed from patterning the stack 214 and a top portion of the hybrid substrate 205. In the illustrated embodiment, a fin-shape structure 222N is formed in the NFET region 208 by patterning the stack 214 and a top portion of the semiconductor substrate 202, and a fin-shape structure 222P is formed in the PFET region 210 by patterning the stack 214, the semiconductor layer 204, and a top portion of the semiconductor substrate 202.

To pattern the stack 214, a hard mask (not shown) may be deposited over the stack 214 to form an etch mask. The hard mask may be a single layer or a multi-layer. For example, the hard mask may include a pad oxide layer and a pad nitride layer over the pad oxide layer. The fin-shape structures 222 may be patterned from the stack 214 and the hybrid substrate 205 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods.

In some implementations, double-patterning or multi-patterning processes may be used to define fin-shape structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shape structures 222 by etching the stack 214 and a top portion of the hybrid substrate 205. The patterned top portion of the hybrid substrate 205 is also denoted as a fin-shape base 212B. In the NFET region 208, the fin-shape base 212B includes a top portion of the semiconductor substrate 202. In the PFET region 210, the fin-shape base 212B includes the semiconductor layer 204 and a top portion of the semiconductor substrate 202. Each of the fin-shape structures 222, which includes the patterned stack 214 and the fin-shape base 212B, extends vertically along the Z direction and lengthwise along the X direction. In some instances, each of the fin-shape structures 222 measures between about 6 nm and about 80 nm wide along the Y direction, and a distance between opposing sidewalls of two adjacent fin-shape structures 222 measures between about 6 nm and about 115 nm along the Y direction.

Still referring to FIG. 10, an isolation feature 224 may be formed adjacent the fin-shape structures 222. In some embodiments, the isolation feature 224 may be formed in the trenches between adjacent fin-shape structures 222 to isolate the fin-shape structures 222 from each other. The isolation feature 224 may also be referred to as a shallow trench isolation (STI) feature 224. By way of example, in some embodiments, a dielectric layer is first deposited over the hybrid substrate 205, filling the trenches with the dielectric layer. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a CMP process. The planarized dielectric layer is further recessed or pulled-back by a dry etching process, a wet etching process, and/or a combination thereof to form the STI feature 224. The fin-shape structures 222 rise above the STI feature 224 after the recessing. The recessed top surface of the STI feature 224 may be leveled with or below the bottom surface of the patterned stack 214.

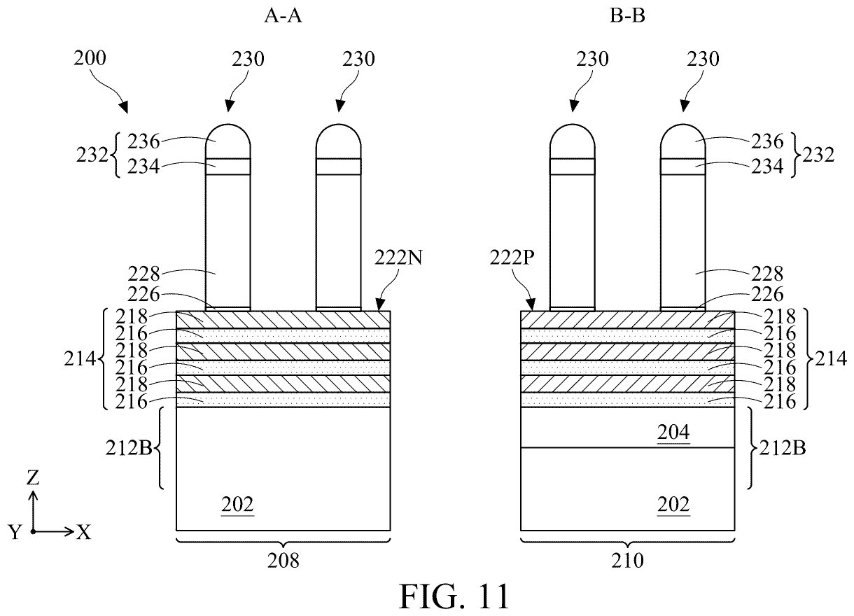

Referring to FIGS. 1 and 11, method 100 includes a block 118 where dummy gate stacks 230 is formed over channel regions of the fin-shape structures 222. FIG. 11 illustrates cross-sectional views cut through A-A and B-B lines in FIG. 10, respectively. In some embodiments, a gate replacement process (or gate-last process) is adopted where the dummy gate stacks 230 serves as a placeholder to undergo various processes and is to be removed and replaced by the functional gate structure. Other processes and configuration are possible. The dummy gate stacks 230 are formed over the fin-shape structures 222 and the fin-shape structures 222 are divided into channel regions underlying the dummy gate stacks 230 and source/drain regions that do not underlie the dummy gate stacks 230. The channel regions are adjacent the source/drain regions with each channel region disposed between two source/drain regions along the X direction.

The formation of the dummy gate stacks 230 may include deposition of layers in the dummy gate stacks 230 and patterning of these layers. Referring to FIG. 11, a dummy dielectric layer 226, a dummy electrode layer 228, and a gate-top hard mask layer 232 may be blanketly deposited over the workpiece 200. In some embodiments, the dummy dielectric layer 226 may be formed on the fin-shape structures 222 using a chemical vapor deposition (CVD) process, an ALD process, an oxygen plasma oxidation process, or other suitable processes. In some instances, the dummy dielectric layer 226 may include silicon oxide. Thereafter, the dummy electrode layer 228 may be deposited over the dummy dielectric layer 226 using a CVD process, an ALD process, or other suitable processes. In some instances, the dummy electrode layer 228 may include polysilicon. For patterning purposes, the gate-top hard mask layer 232 may be deposited on the dummy electrode layer 228 using a CVD process, an ALD process, or other suitable processes. The gate-top hard mask layer 232, the dummy electrode layer 228 and the dummy dielectric layer 226 may then be patterned to form the dummy gate stack 230, as shown in FIG. 11. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the gate-top hard mask layer 232 may include a silicon oxide layer 234 and a silicon nitride layer 236 over the silicon oxide layer 234.

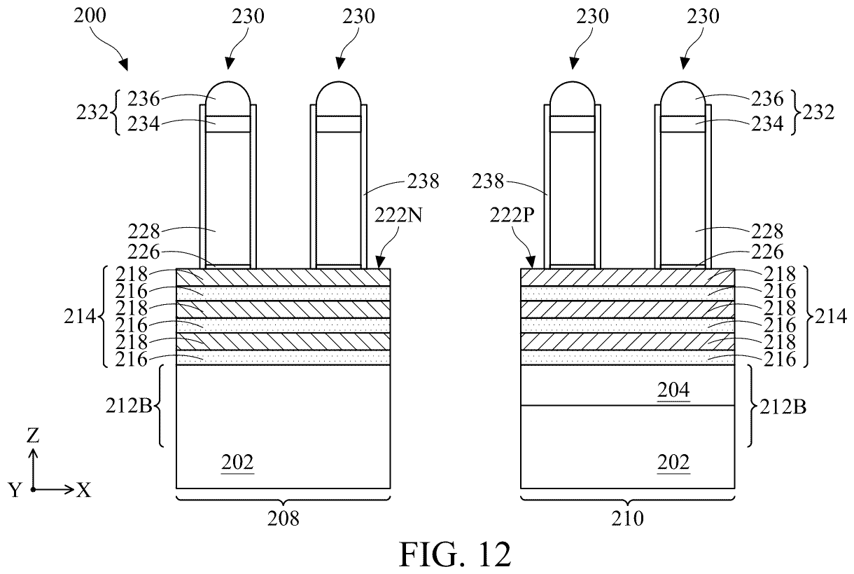

Referring to FIGS. 1 and 12, method 100 includes a block 120 where a gate spacer layer 238 is deposited over the dummy gate stacks 230. In some embodiments, the gate spacer layer 238 is deposited conformally over the workpiece 200, including over top surface and sidewalls of the dummy gate stacks 230. The term “conformally” may be used herein for ease of description of a layer having substantially uniform thickness over various regions. The gate spacer layer 238 may be a single layer or a multi-layer. The at least one layer in the gate spacer layer 238 may include silicon carbonitride, silicon oxycarbide, silicon oxycarbonitride, or silicon nitride. The gate spacer layer 238 may be deposited over the dummy gate stack 230 using processes such as, a CVD process, a subatmospheric CVD (SACVD) process, an ALD process, or other suitable process. In one embodiment, the gate spacer layer 238 includes a first layer and a second layer disposed over the first layer. The first layer may include silicon oxynitride and the second layer may include silicon nitride. In some instances, the gate spacer layer 238 measures between about 3 nm and about 8 nm thick along the X direction.

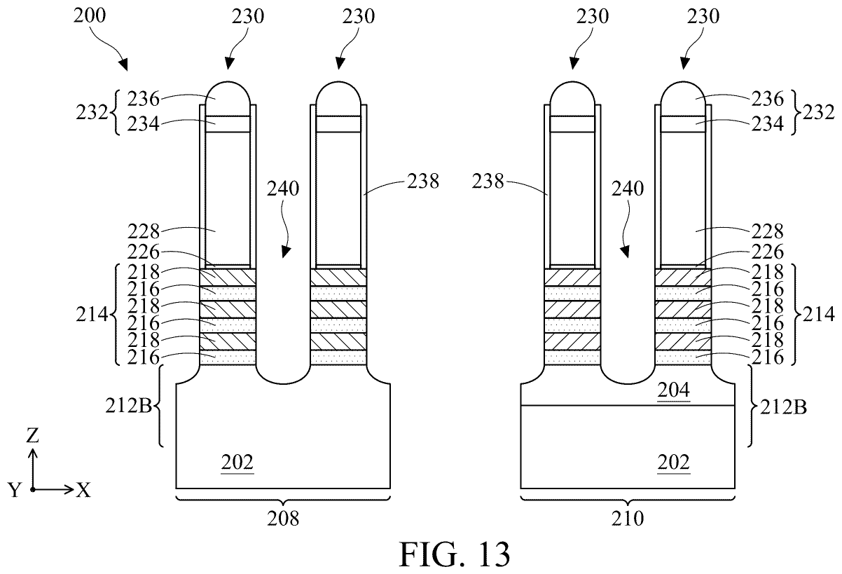

Referring to FIGS. 1 and 13, method 100 includes a block 122 where source/drain regions of the fin-shape structures 222 are recessed to form source/drain trenches 240. In some embodiments, the source/drain regions that are not covered by the dummy gate stacks 230 and the gate spacer layer 238 are etched by a dry etch or a suitable etching process to form the source/drain trenches 240. For example, the dry etch process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBR₃), an iodine-containing gas, other suitable gases and/or plasmas, and/or combinations thereof. In some embodiments represented in FIG. 13, the source/drain regions of the fin-shape structures 222 are recessed to expose sidewalls of the sacrificial layers 216 and the channel layers 218. In some implementations, the source/drain trenches 240 extend below the stack 214 into the hybrid substrate 205. As shown in FIG. 13, the semiconductor substrate 202 is exposed in the source/drain trenches 240 in the NFET region 208, and the semiconductor layer 204 is exposed in the source/drain trenches 240 in the PFET region 210. The semiconductor substrate 202 remains covered by the semiconductor layer 204 in the PFET region 210.

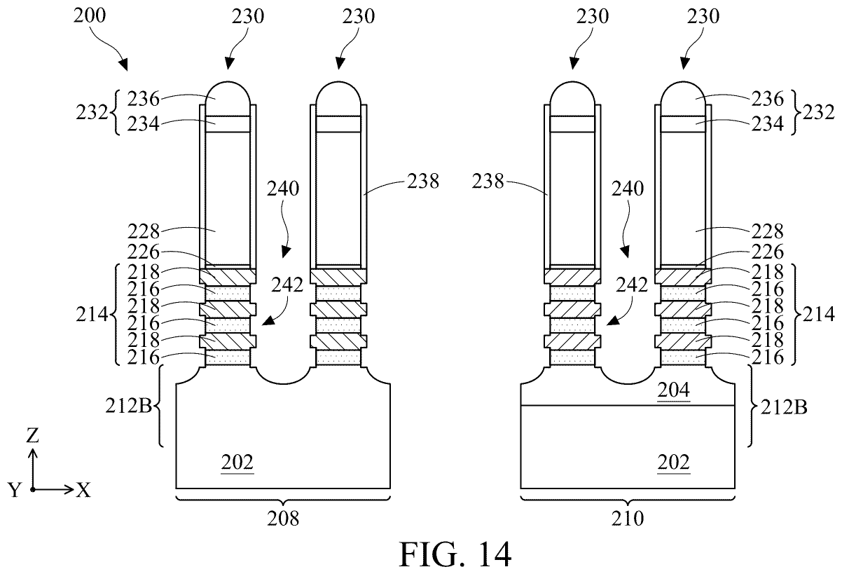

Referring to FIGS. 1, 14, and 15, method 100 includes a block 124 where inner spacer features 244 are formed. Operation at block 124 may include selective and partial removal of the sacrificial layers 216 to form inner spacer recesses 242, deposition of inner spacer material over the workpiece 200, and etch back the inner spacer material to form inner spacer features 244 in the inner spacer recesses 242. The sacrificial layers 216 exposed in the source/drain trenches 240 (shown in FIG. 14) are selectively and partially recessed to form inner spacer recesses 242. The end portions of the channel layers 218 as exposed by the inner spacer recesses 242 may also suffer from some etching loss due to limited etching contrast, such that the end portions of the channel layers 218 may be moderately etched and become thinner than center portions of the channel layers 218 measured along the Z direction. In an embodiment where the channel layers 218 consist essentially of silicon (Si) and sacrificial layers 216 consist essentially of silicon germanium (SiGe), the selective recess of the sacrificial layers 216 may be performed using a selective wet etch process or a selective dry etch process. The selective and partial recess of the sacrificial layers 216 may include a SiGe oxidation process followed by a SiGe oxide removal. In that embodiment, the SiGe oxidation process may include use of ozone. In some other embodiments, the selective dry etching process may include use of one or more fluorine-based etchants, such as fluorine gas or hydrofluorocarbons. The selective wet etching process may include an APM etch (e.g., ammonia hydroxide-hydrogen peroxide-water mixture).

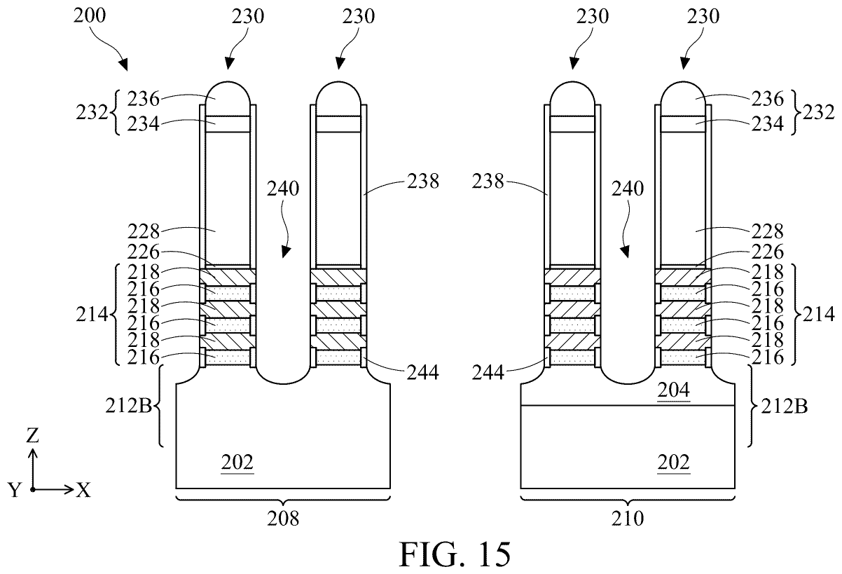

After the inner spacer recesses 242 are formed, the inner spacer material is deposited over the workpiece 200, including over the inner spacer recesses 242. The inner spacer material may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. While not explicitly shown, the inner spacer material may be a single layer or a multilayer. In some implementations, the inner spacer material may be deposited using CVD, PECVD, SACVD, ALD or other suitable methods. The inner spacer material is deposited into the inner spacer recesses 242 as well as over the sidewalls of the channel layers 218 exposed in the source/drain trenches 240. Referring to FIG. 15, the deposited inner spacer material is then etched back to remove the inner spacer material from the sidewalls of the channel layers 218 to form the inner spacer features 244 in the inner spacer recesses 242. At block 124, the inner spacer material may also be removed from the top surfaces and/or sidewalls of the gate-top hard mask layer 232 and the gate spacer layer 238. In some implementations, the etch back operations performed at block 124 may include use of hydrogen fluoride (HF), fluorine gas (F₂), hydrogen (H₂), ammonia (NH₃), nitrogen trifluoride (NF₃), or other fluorine-based etchants. As shown in FIG. 15, each of the inner spacer features 244 is in direct contact with the recessed sacrificial layers 216 and is disposed between two neighboring channel layers 218. In some instances, each of the inner spacer features 244 measures between about 3 nm and about 5 nm thick along the X direction.

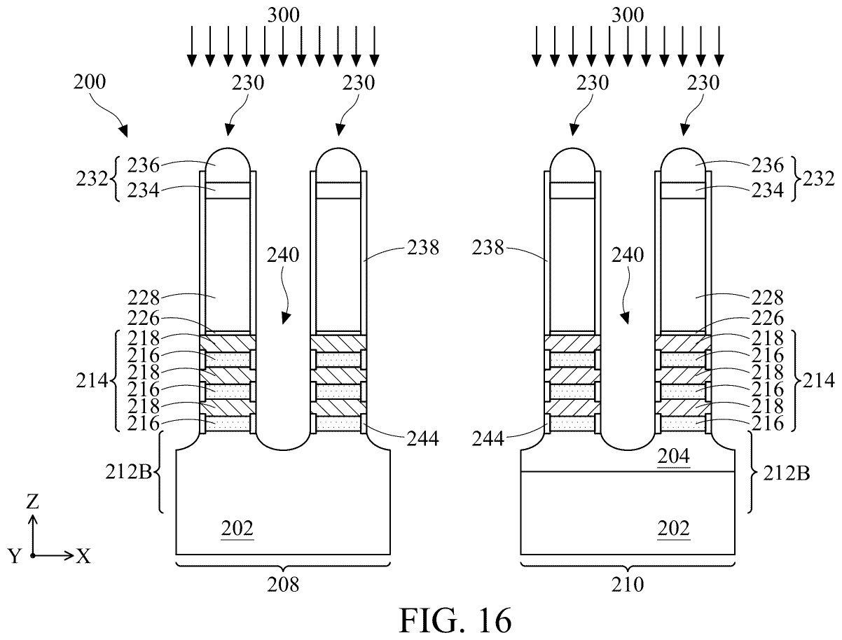

Referring to FIGS. 1 and 16, method 100 includes a block 126 where a cleaning process 300 is performed. The cleaning process 300 may include a dry clean, a wet clean, or a combination thereof. In some examples, the wet clean may include use of standard clean 1 (RCA SC-1, a mixture of deionized (DI) water, ammonium hydroxide, and hydrogen peroxide), standard clean 2 (RCA SC-2, a mixture of DI water, hydrochloric acid, and hydrogen peroxide), SPM (a sulfuric peroxide mixture), and/or hydrofluoric acid for oxide removal. The dry clean process may include helium (He) and hydrogen (H₂) treatment at a temperature between about 250° C. and about 550° C. and under a pressure between about 75 mTorr and about 155 mTorr. The hydrogen treatment may convert silicon on the surface to silane (SiH₄), which may be pumped out for removal. In some implementations, the cleaning process is configured to selectively remove or trim a portion of the channel layers without substantially removing the inner spacer features 244. The cleaning process 300 may remove surface oxide and debris in order to ensure a clean semiconductor surface, which facilitates growth of a base epitaxial layer at block 128.

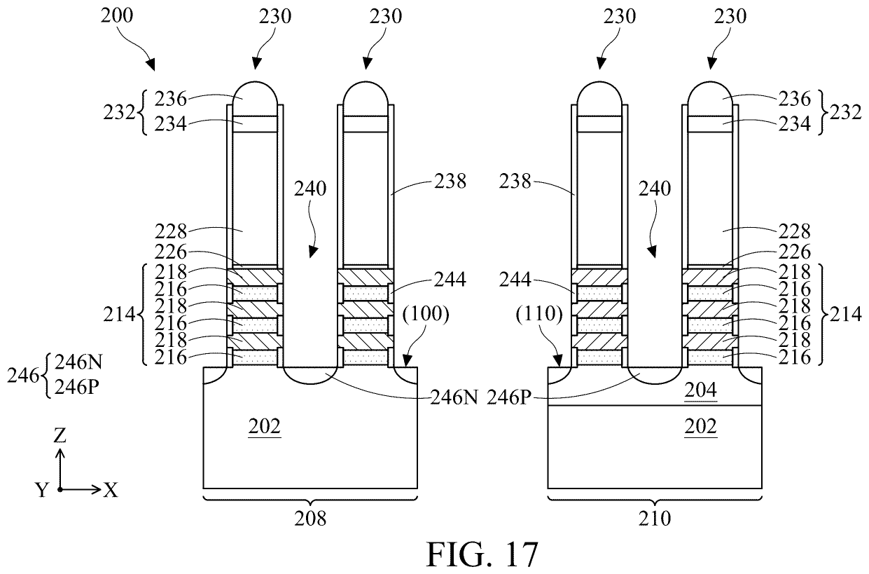

Referring to FIGS. 1 and 17, method 100 includes a block 128 where a base epitaxial layer 246 is deposited in the bottom of each of the source/drain trenches 240. In the illustrated embodiment, the base epitaxial layer 246 formed in the NFET region 208 is denoted as the base epitaxial layer 246N, and the base epitaxial layer 246 formed in the PFET region 210 is denoted as the base epitaxial layer 246P. The base epitaxial layer 246N carries the same crystalline structure of the semiconductor substrate 202. That is, the top surface of the base epitaxial layer 246N has a (100) crystal plane. The base epitaxial layer 246P carries the same crystalline structure of the semiconductor layer 204. That is, the top surface of the base epitaxial layer 246P has a (110) crystal plane. In some embodiments, the base epitaxial layer 246 includes the same material as the channel layers 218, such as silicon (Si). Particularly, the base epitaxial layer 246 is made of non-doped silicon. In some embodiments, the base epitaxial layer 246 includes the same material as the sacrificial layers 216, such as silicon germanium (SiGe), with the germanium (Ge) content the same or different from the sacrificial layers 216. Particularly, the base epitaxial layer 246 is made of non-doped silicon germanium. In various embodiments, the base epitaxial layer 246 is dopant-free, where for example, no intentional doping is performed during the epitaxial growth process. The dopant-free base epitaxial layer 246 provides a high resistance path at the bottom of the source/drain trenches 240, such that the leakage current into the substrate is suppressed.

Suitable epitaxial processes for block 128 include vapor-phase epitaxy (VPE), molecular beam epitaxy (MBE), selective CVD, and/or other suitable processes. Various deposition parameters can be tuned to selectively deposit the semiconductor material on exposed semiconductor surfaces in the source/drain trenches 240, such as deposition gas composition, carrier gas composition, deposition gas flow rate, carrier gas flow rate, deposition time, deposition pressure, deposition temperature, source power, RF bias voltage, DC bias voltage, RF bias power, DC bias power, other suitable deposition parameters, or combinations thereof. In some embodiments, the workpiece 200 is exposed to a deposition mixture that includes DCS and/or SiH₄ (silicon-containing precursor), H₂ (carrier precursor), and HCl (etchant-containing precursor) when forming the base epitaxial layer 246. In some embodiments, the selective CVD process implements a deposition temperature of about 600° C. to about 750° C. In some embodiments, the selective CVD process implements a deposition pressure of about 10 Torr to about 100 Torr. In some embodiments, the selective CVD process is configured as a bottom-up deposition process, such that base epitaxial layer 246 grows from the exposed semiconductor surface at the bottom of the source/drain trenches 240, but not from exposed end portions of the channel layers 218. The growth of the base epitaxial layer 246 is under time control such that the top surface of the base epitaxial layer 246 can be fined tuned to be level with, below, or above a bottom surface of the bottommost sacrificial layer 216 depending on device performance needs. If the top surface of the base epitaxial layer 246 is below the bottom surface of the bottommost sacrificial layer 216, the base epitaxial layer 246 may be free of physical contact with the bottommost inner spacer feature 244. Otherwise, the base epitaxial layer 246 may be in physical contact with the bottommost inner spacer feature 244.

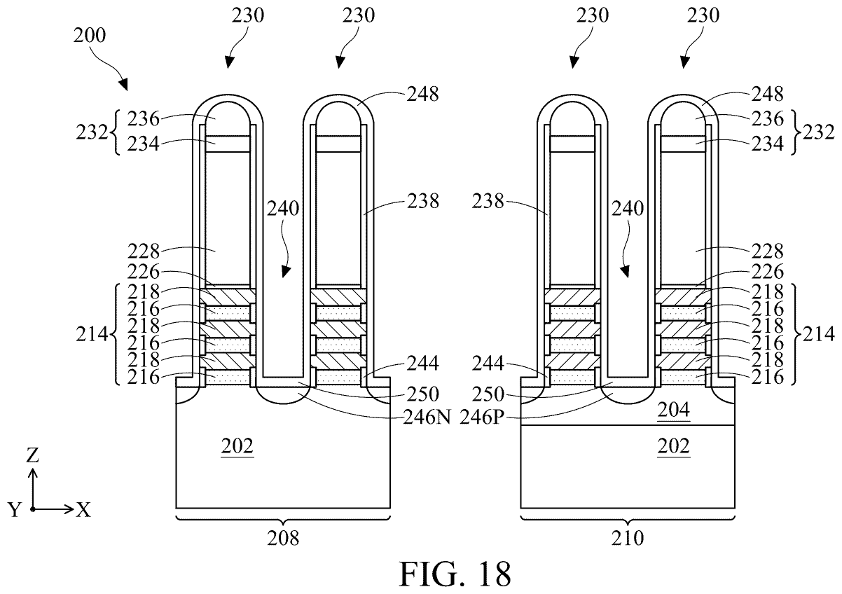

Referring to FIGS. 1, 18, and 19, method 100 includes a block 130 where a dielectric film 250 is formed in the bottom of the source/drain trenches 240 and above the base epitaxial layer 246. Operation at block 130 may include deposition of dielectric material 248 over the workpiece 200, and etch back the dielectric material 248 to form the dielectric film 250 in the bottom of the source/drain trenches 240. The dielectric material 248 is deposited over the workpiece 200, including over sidewalls and bottom surfaces of the source/drain trenches 240 and over sidewalls and top surfaces of the dummy gate stacks 230, as shown in FIG. 18. In some embodiments, the dielectric material 248 may include a metal oxide or a metal nitride, such as La₂O₃, Al₂O₃, ZnO, ZrN, Zr₂Al₃O₉, TiO₂, TaO₂, ZrO₂, HfO₂, Y₂O₃, AlON, TaCN, other suitable material(s), or combinations thereof. In some embodiments, the dielectric material 248 may include silicon oxide, silicon oxycarbonitride, silicon nitride, silicon oxynitride, carbon-rich silicon carbonitride, or a low-k dielectric material. In some implementations, the dielectric material 248 may be deposited using a directional deposition process, such as PEALD with RF plasma treatment, or other suitable methods. Under the directional plasma treatment, the horizontal portion of the dielectric material 248 receives more plasma bombardment than the vertical portion such that horizontal portion and the vertical portion have different etch selectivity, allowing the etching back of the dielectric material 248 with horizontal portion remaining at the bottom of the source/drain trenches 240. Alternatively, the directional deposition process may form the dielectric material 248 with thicker horizontal portions (e.g., on the bottom surface of the source/drain trenches 240) and thinner vertical portions (e.g., on the sidewalls of the dummy gate stacks 230), which also allows the horizontal portion remain after the etching back of the dielectric material 248. In some embodiments, the horizontal portion of the dielectric material 248 has a thickness ranging from about 4.5 nm to about 10.5 nm, while the vertical portion of the dielectric material 248 has a thinner thickness ranging from about 3.5 nm to about 5.5 nm.

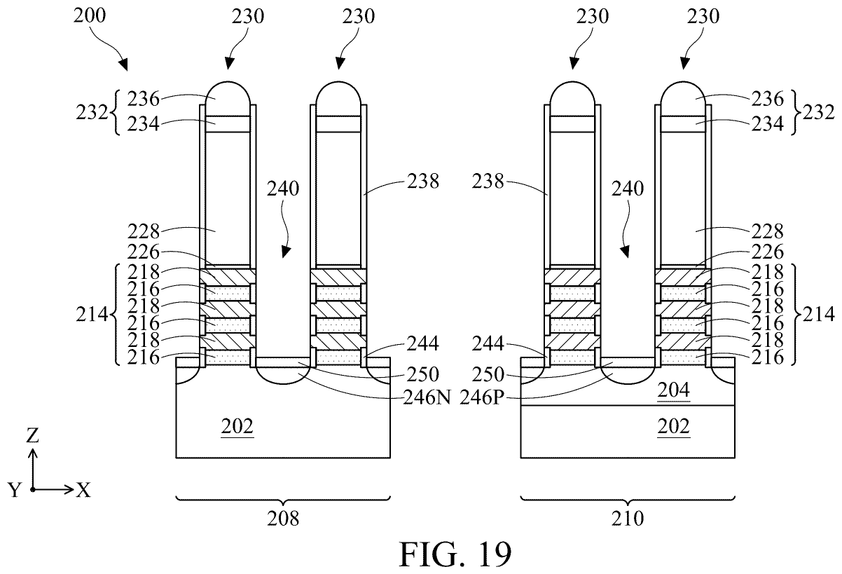

Referring to FIG. 19, the deposited dielectric material 248 is then etched back to remove the thinner vertical portions from the sidewalls of the dummy gate stacks 230. In some implementations, the etch back operations performed at block 130 may include use of hydrogen fluoride (HF), fluorine gas (F₂), hydrogen (H₂), ammonia (NH₃), nitrogen trifluoride (NF₃), or other fluorine-based etchants. The horizontal portion atop the dummy gate stacks 230 may also be removed due to the loading effect, while the horizontal portion in the bottom of the source/drain trenches 240 is thinned down but still remains as the dielectric film 250, which covers the base epitaxial layer 246. In some embodiments, the dielectric film 250 has a thickness (measured in Z direction) in a range from about 1 nm to about 5 nm. The top surface of the dielectric film 250 may be above the bottom surface of the bottommost sacrificial layer 216, but lower than the top surface of the bottommost sacrificial layer 216. The bottommost inner spacer feature 244 may have a height measured in the Z direction from about 5 nm to about 7 nm, such that the dielectric film 250 is in physical contact with the bottommost inner spacer feature 244, while a top portion of the bottommost inner spacer feature 244 is above the top surface of the dielectric film 250. In the depicted embodiment, the top surface of the dielectric film 250 has a flat profile. Alternatively, the top surface of the dielectric film 250 may have a concave profile or a convex profile.

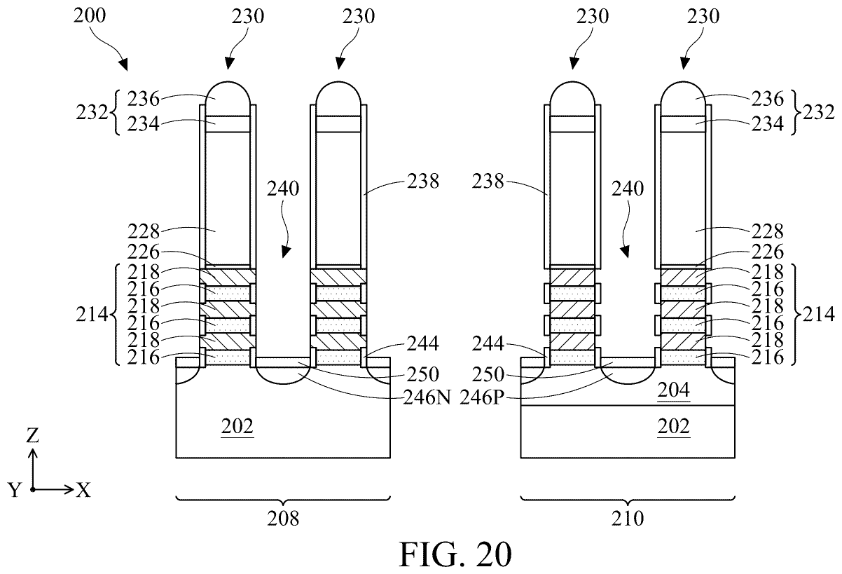

Referring to FIGS. 1 and 20, method 100 includes a block 132 where channel layers 218 in the PFET region 210 are laterally recessed. The etch back of the channel layers 218 in the PFET region 210 results in a smaller channel length in the PFET region 210 than in in the NFET region 208. The etch back of the channel layers 218 in the PFET region 210 pushes back the junction closer to the gate structures in the PFETs, which is beneficial to the PFET performance. In some implementations, a resist layer is formed over the NFET region 208, while the PFET region 210 is exposed. The etch back operations performed at block 132 may include use of hydrogen fluoride (HF), fluorine gas (F₂), hydrogen (H₂), ammonia (NH₃), nitrogen trifluoride (NF₃), or other fluorine-based etchants. In the illustrated embodiment, end portions of the channel layers 218 vertically stacked between the inner spacer features 244 are removed from the PFET region 210. In some embodiments, operations at block 132 are optional, and method 100 may proceed to block 134 without performing operations at block 132.

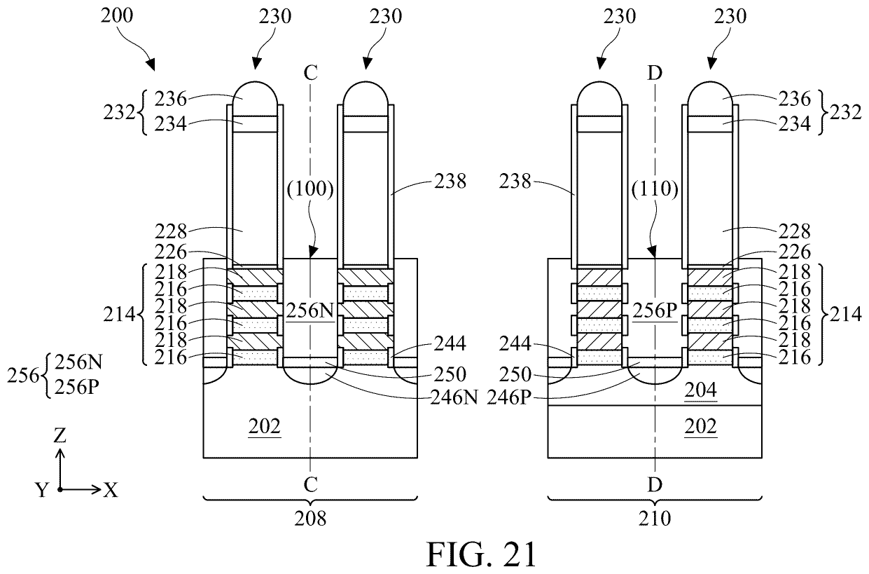

Referring to FIGS. 1 and 21, method 100 includes a block 134 where source/drain features 256 are epitaxially and selectively formed from the exposed sidewalls of the channel layers 218 while sidewalls of the sacrificial layers 216 remain covered by the inner spacer features 244. Suitable epitaxial processes for block 134 include vapor-phase epitaxy (VPE), ultra-high vacuum CVD (UHV-CVD), molecular beam epitaxy (MBE), and/or other suitable processes. In the illustrated embodiment, the source/drain features 256 formed in the NFET region 208 are denoted as the source/drain features 256N, and the source/drain features 256 formed in the PFET region 210 are denoted as the source/drain features 256P. The source/drain features 256N carry the same crystalline structure of the semiconductor substrate 202 and the channel layers 218 in the NFET region 208. That is, the top surface of the source/drain features 256N has a (100) crystal plane. The source/drain features 256P carry the same crystalline structure of the semiconductor layer 204 and the channel layers 218 in the PFET region 210. That is, the top surface of the source/drain features 256P has a (110) crystal plane.

The source/drain features 256N and 256P may be formed separately. For example, the source/drain features 256N may be epitaxially grown in the source/drain trenches 240 in the NFET region 208, while the source/drain trenches 240 in the PFET region 210 are covered under a resist layer which blocks epitaxial growth from occurring in the PFET region 210. After the source/drain features 256N are formed, the source/drain features 256P are epitaxially grown in the source/drain trenches 240 in the PFET region 210, while the NFET region 208 is covered under a resist layer which blocks epitaxial growth from occurring in the NFET region 208. Alternatively, the source/drain features 256P may be epitaxially grown prior to the source/drain features 256N.

In the NFET region 208, the source/drain features 256N may include Si, SiP, SiAs, SiC, SiCP, SiCAs, or other suitable semiconductor material. The source/drain features 256N may be doped with dopants such as arsenic (As) or phosphorus (P). In one example, the source/drain features 256N is doped with As or P with a molar concentration from about 5×10²⁰ cm⁻³ to about 4×10²¹ cm⁻³. When the source/drain features 256N includes carbon, a carbon atomic percentage may range from about 10% to about 20%. In some embodiments, the source/drain features 256N includes the same semiconductor material with the base epitaxial layer 246N but with a higher dopant concentration. For example, the source/drain features 256N and the base epitaxial layer 246N may both include silicon, while the source/drain features 256N is doped with phosphorus, while the base epitaxial layer 246N is substantially free of dopant.

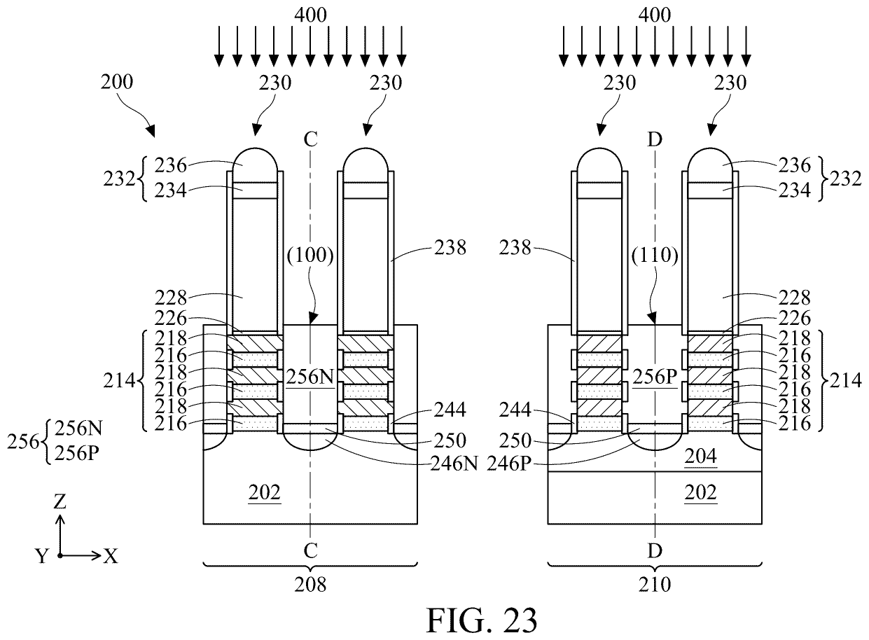

In the PFET region 210, the source/drain features 256P may include SiGe, SiSn, or other suitable semiconductor material. The source/drain features 256P may be doped with dopants such as germanium (Ge) or boron (B). In one example, the source/drain features 256P is doped with boron (B) and the source/drain features 256P includes SiGeB, SiSnB, or other suitable semiconductor material with a boron molar concentration from about 4×10²⁰ cm⁻³ to about 2×10²¹ cm⁻³. When the source/drain features 256P includes germanium, a germanium atomic percentage may range from about 10% to about 60%. In some embodiments, the source/drain features 256P includes the same semiconductor material with the base epitaxial layer 246P but with a higher dopant concentration. For example, the source/drain features 256P and the base epitaxial layer 246P may both include SiGe, while the source/drain features 256P is doped with boron, while the base epitaxial layer 246P is substantially free of dopant. If the channel layers 218 in the PFET region 210 are laterally recessed at block 132, the source/drain features 256P have lateral protruding portions extends to a position directly under the gate spacer layer 238 (or even directly under the dummy gate stacks 230) and are vertically stacked by the inner spacer features 244, as shown in FIG. 23. In furtherance, the source/drain features 256P may have a larger volume than the source/drain features 256N due to those extra protruding portions.

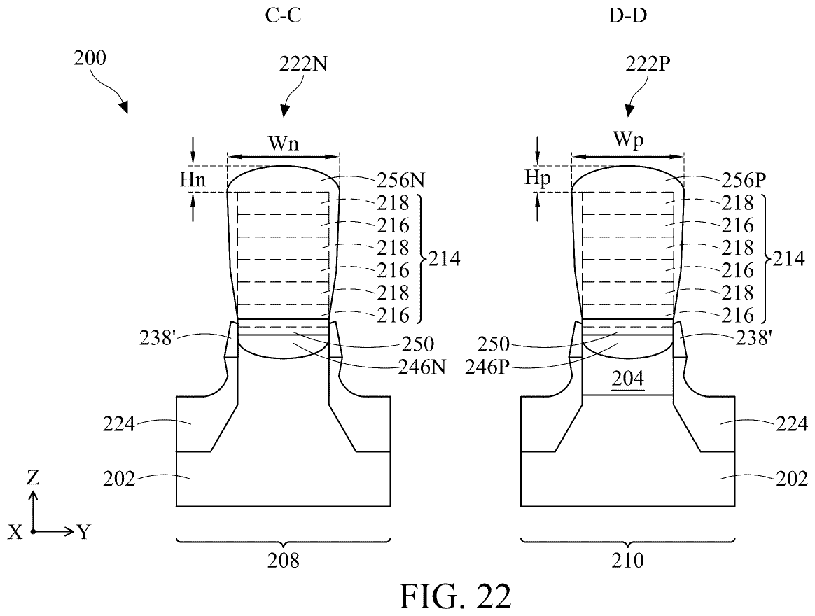

FIG. 22 illustrates cross-sectional views cut through C-C and D-D lines in FIG. 21, respectively. In both the NFET region 208 and the PFET region 210, the gate spacer layer 238 formed at block 120 is also deposited on sidewalls of the fin-shape structures 222N and 222P, respectively, in the source/drain regions. The portion of the gate spacer layer 238 in the source/drain regions is also referred to as the fin spacer layer 238′. After the fin-shape structures 222N and 222P are recessed and the base epitaxial layers 246N and 246P are epitaxially grown, the fin spacer layer 238′ is over sidewalls of the base epitaxial layers 246N and 246P. The fin spacer layer 238′ confines the epitaxial growth of the base epitaxial layer 246N and 246P in the Y direction. The recessing of the fin-shape structures 222N and 222P also recesses the STI feature 224. The fin spacer layer 238′ may protect a portion of the STI feature 224 directly thereunder from etching loss, while other portions of the STI feature 224 is recessed. A bottom surface of the base epitaxial layer 246N and 246P may be above the recessed top surface of the STI feature 224. A bottom surface of the semiconductor layer 204 may also be above the recess top surface of the STI feature 224.

Still referring to FIG. 22, for clarity of the spatial relationship, the channel layers 218 and the sacrificial layers 216 in the channel region are overlayed as represented by boxes of dashed lines. In some embodiments, a top surface of the dielectric film 250 may be above the bottom surface of the bottommost sacrificial layer 216 and below the top surface of the bottommost sacrificial layer 216. In some embodiments, a bottom surface of the dielectric film 250 may be level with the bottom surface of the bottommost sacrificial layer 216. In some embodiments, a thickness of the dielectric film 250 after the epitaxial growth of the source/drain features 256N and 256P may range from about 0.5 nm to about 6.5 nm. In the NFET region 208, a top surface of the source/drain feature 256N may grow above the top surface of the fin-shape structure 222N (i.e., the top surface of the topmost channel layer 218). In some embodiments, the top surface of the source/drain feature 256N is above the top surface of the fin-shape structure 222N for a distance Hn ranging from about 1 nm to about 11 nm. In some embodiments, a width Wn of the source/drain feature 256N measured in the Y direction may range from about 33 nm to about 42 nm. In the PFET region 210, a top surface of the source/drain feature 256P may grow above the top surface of the fin-shape structure 222P (i.e., the top surface of the topmost channel layer 218). In some embodiments, the top surface of the source/drain feature 256P is above the top surface of the fin-shape structure 222P for a distance Hp ranging from about 1 nm to about 11 nm. In some embodiments, a width Wp of the source/drain feature 256P measured in the Y direction may range from about 33 nm to about 42 nm.

Referring to FIGS. 1 and 23, method 100 includes a block 136 where the workpiece 200 is annealed in an anneal process 400. In some implementation, the anneal process 400 may include a rapid thermal anneal (RTA) process, a laser spike anneal process, a flash anneal process, or a furnace anneal process. The anneal process 400 may include a peak anneal temperature between about 900° C. and about 1000° C. In these implementations, the peak anneal temperature may be maintained for a duration measured by seconds or microseconds. Through the anneal process 400, a desired electronic contribution of the p-type dopant in the semiconductor host, such as silicon germanium (SiGe) or germanium (Ge), may be obtained. The anneal process 400 may generate vacancies that facilitate movement of the p-type dopant from interstitial sites to substitutional lattice sites and reduce damages or defects in the lattice of the semiconductor host.

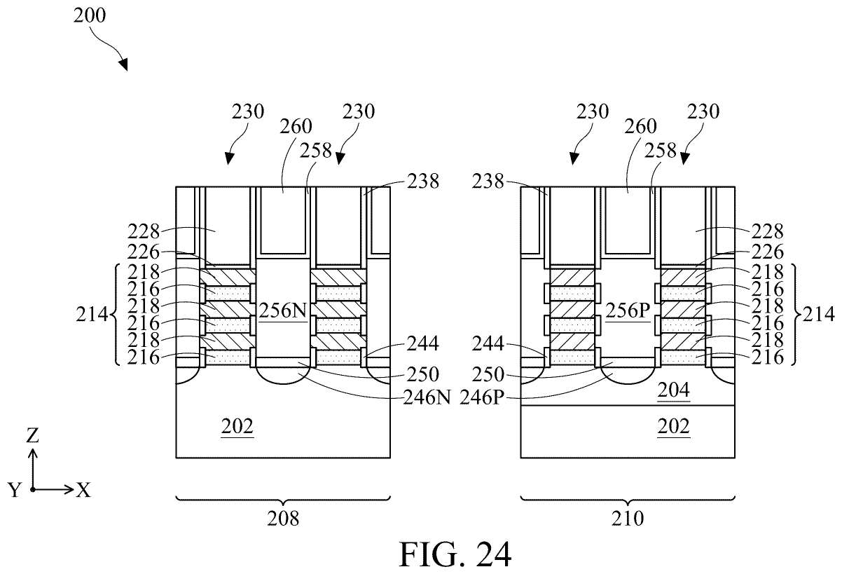

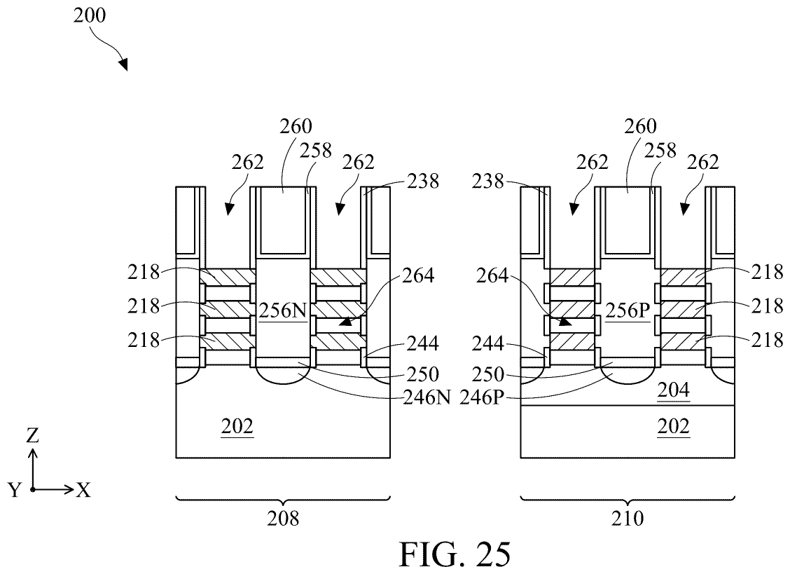

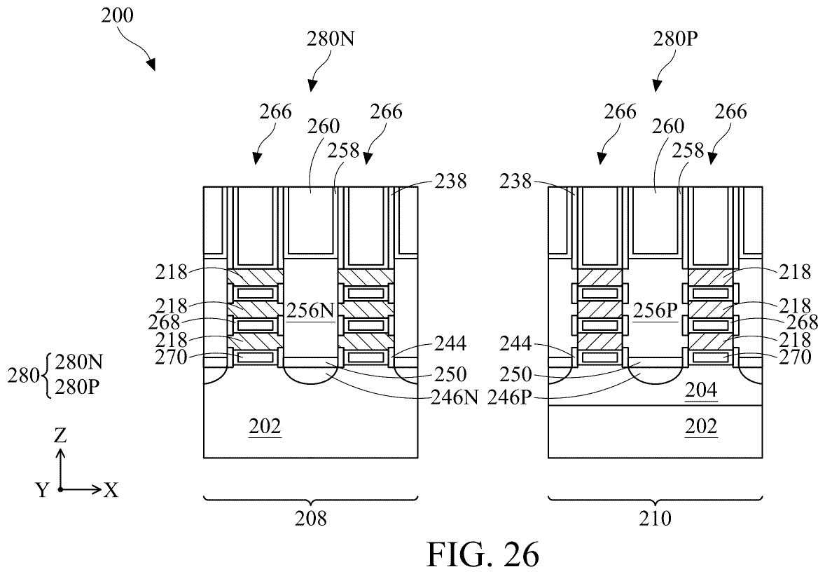

Referring to FIGS. 1 and 24-26, method 100 includes a block 138 where further processes are performed. Such further processes may include, for example, deposition of a contact etch stop layer (CESL) 258 over the workpiece 200 (shown in FIG. 24), deposition of an interlayer dielectric (ILD) layer 260 over the CESL 258 (shown in FIG. 24), removal of the dummy gate stacks 230 (shown in FIG. 25), selective removal of the sacrificial layers 216 in the channel regions to release the channel layers 218 as channel members (shown in FIG. 25), and formation of a gate structure 266 over the channel regions (shown in FIG. 26).

Referring now to FIG. 24, the CESL 258 is formed prior to forming the ILD layer 260. In some examples, the CESL 258 includes silicon nitride, silicon oxynitride, and/or other materials known in the art. The CESL 258 may be formed by ALD, plasma-enhanced chemical vapor deposition (PECVD) process and/or other suitable deposition processes. The ILD layer 260 is then deposited over the CESL 258. In some embodiments, the ILD layer 260 includes materials such as tetraethylorthosilicate (TEOS) oxide, undoped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 260 may be deposited by a PECVD process or other suitable deposition technique. In some embodiments, after formation of the ILD layer 260, the workpiece 200 may be annealed to improve integrity of the ILD layer 260. As shown in FIG. 24, the CESL 258 is disposed directly on top surfaces of the source/drain features 256. After the deposition of the CESL 258 and the ILD layer 260, the workpiece 200 may be planarized by a planarization process to expose the dummy gate stacks 230. For example, the planarization process may include a chemical mechanical planarization (CMP) process. After the CMP process, a distance from the top surface of the dummy gate stack 230 to the top surface of the topmost channel layer 218 may measure between 5 nm and about 50 nm along the Z direction.

Exposure of the dummy gate stacks 230 allows the removal of the dummy gate stacks 230 and release of the channel layers 218, illustrated in FIG. 25. In some embodiments, the removal of the dummy gate stacks 230 results in gate trenches 262 over the channel regions. The removal of the dummy gate stacks 230 may include one or more etching processes that are selective to the material of the dummy gate stacks 230. For example, the removal of the dummy gate stacks 230 may be performed using as a selective wet etch, a selective dry etch, or a combination thereof that is selective to the dummy gate stacks 230. After the removal of the dummy gate stacks 230, sidewalls of the channel layers 218 and the sacrificial layers 216 in the channel regions are exposed in the gate trenches 262. After the removal of the dummy gate stacks 230, the method 100 may include operations to selectively remove the sacrificial layers 216 between the channel layers 218 in the channel regions. The selective removal of the sacrificial layers 216 releases the channel layers 218 to form channel members (also numbered as 218). The selective removal of the sacrificial layers 216 also leaves behind space 264 between the channel members 218. The selective removal of the sacrificial layers 216 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

Referring to FIG. 26, the method 100 may include further operations to form the gate structures 266 to wrap around each of the channel members 218. In some embodiments, the gate structures 266 is formed within the gate trenches 262 and into the space 264 left behind by the removal of the sacrificial layers 216. In this regard, the gate structures 266 wraps around each of the channel members 218. The gate structures 266 include a gate dielectric layer 268 and a gate electrode layer 270 over the gate dielectric layer 268. In some embodiments, while not explicitly shown in the figures, the gate dielectric layer 268 includes an interfacial layer and a high-K gate dielectric layer. High-K dielectric materials, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-K gate dielectric layer may include hafnium oxide. Alternatively, the high-K gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material. The high-K gate dielectric layer may be formed by ALD, physical vapor deposition (PVD), CVD, oxidation, and/or other suitable methods.

The gate electrode layer 270 of the gate structures 266 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 270 may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 270 may be formed by ALD, PVD, CVD, e-beam evaporation, or other suitable process. In various embodiments, a CMP process may be performed to remove excessive metal, thereby providing a substantially planar top surface of the gate structures 266. The gate structures 266 includes portions that interpose between channel members 218 in the channel regions.

Still referring to FIG. 26, upon conclusion of the operations at block 138, transistors 280, particularly one or more n-type transistors (NFETs) 280N in the NFET region 208 and one or more p-type transistors (PFETs) 280P in the PFET region 210, are substantially formed. The transistors 280 include channel members 218 that are vertically stacked along the Z direction. Each of the channel members 218 is wrapped around by the respective gate structure 266. The channel members 218 extend or are sandwiched between two source/drain features 256 along the X direction. Underneath the source/drain features 256 are the dielectric film 250 and the base epitaxial layer 246. The dielectric film 250 and the base epitaxial layer 246 exhibit high resistivity, thus providing a high resistance path from the source/drain features 256 to the substrate, such that the leakage current into the substrate is suppressed. Particularly, in the NFET region 208, the channel members 218, the base epitaxial layer 246N, the source/drain features 256N all carry the (100) crystalline structure, which is the same as the semiconductor substrate 202; in the PFET region 210, the channel members 218, the base epitaxial layer 246P, the source/drain features 256P all carry the (110) crystalline structure, which is the same as the semiconductor layer 204. The (110) crystalline structure of the channel members 218 provide higher carrier mobility for the p-type transistors, meanwhile the (110) crystalline structure of the source/drain features 256P mitigate the loss of compressive strain due to the insertion of the dielectric film 250 underneath the source/drain features 256P. Therefore, AC and DC performances of transistors in the NFET region 208 and the PFET region 210 are both optimized without sacrificing DC performance of p-type transistors in the PFET region 210.

In one exemplary aspect, the present disclosure is directed to a method. The method includes bonding a first semiconductor substrate having (110) orientation on a second semiconductor substrate having (100) orientation, forming a stack over the first semiconductor substrate, the stack comprising a plurality of channel layers interleaved by a plurality of sacrificial layers, patterning the stack to form a fin-shape structure, the fin-shape structure comprising a channel region and a source/drain region, forming a dummy gate stack over the channel region of the fin-shape structure, depositing a gate spacer layer over the dummy gate stack, recessing the source/drain region to form a source/drain trench that exposes sidewalls of the plurality of channel layers and the plurality of sacrificial layers, partially recessing the plurality of sacrificial layers to form a plurality of inner spacer recesses, forming a plurality of inner spacer features in the plurality of inner spacer recesses, forming a dielectric film in the source/drain trench, epitaxially growing an epitaxial feature over the dielectric film, the epitaxial feature being in contact with the plurality of channel layers, the epitaxial feature having (110) orientation, after the forming of the epitaxial feature, removing the dummy gate stack, releasing the plurality of channel layers in the channel region as a plurality of channel members, and forming a gate structure wrapping around each of the plurality of channel members. In some embodiments, the method also includes prior to the depositing of the dielectric film, depositing a base epitaxial layer in the source/drain trench. In some embodiments, the base epitaxial layer is dopant free. In some embodiments, the base epitaxial layer has (110) orientation. In some embodiments, the channel layers in the stack have (110) orientation. In some embodiments, the sacrificial layers in the stack have (110) orientation. In some embodiments, the epitaxial feature is doped with a p-type dopant. In some embodiments, the epitaxial feature comprises silicon germanium. In some embodiments, the forming of the dielectric film includes depositing a dielectric layer over a bottom surface and sidewall surfaces of the source/drain trench, and removing the dielectric layer from the sidewall surfaces of the source/drain trench. In some embodiments, the fin-shape structure includes the first semiconductor substrate and a top portion of the second semiconductor substrate.

In another exemplary aspect, the present disclosure is directed to a method. The method includes forming a hybrid substrate having a first region with a top surface in a (100) crystal plane and a second region with a top surface in a (110) crystal plane, patterning the second region to form a fin-shape substrate, forming a plurality of channel members disposed over the fin-shape substrate, forming a plurality of inner spacer features interleaving the plurality of channel members, depositing a dielectric material layer on the plurality of inner spacer features and over a top surface of the fin-shape substrate, etching back the dielectric material layer to form a dielectric film, depositing an epitaxial feature over the dielectric film, the epitaxial feature being in contact with the plurality of channel members, the epitaxial feature having a top surface in a (110) crystal plane, and forming a gate structure wrapping around each of the plurality of channel members. In some embodiments, the method also includes prior to the depositing of the dielectric material layer, depositing a base epitaxial layer on the top surface of the fin-shape substrate, the base epitaxial layer having a top surface in a (110) crystal plane. In some embodiments, the forming of the hybrid substrate includes bonding a first semiconductor substrate having a top surface in a (110) crystal plane on a second semiconductor substrate having a top surface in a (100) crystal plane, removing the first semiconductor substrate from the first region, thickening the second semiconductor substrate in the first region, and planarizing the first semiconductor substrate and the second semiconductor substrate. In some embodiments, the dielectric film is in physical contact with a bottommost one of the plurality of inner spacer features. In some embodiments, the method also includes after the etching back of the dielectric material layer, laterally recessing the channel members. In some embodiments, the epitaxial feature includes a lateral protruding portion vertically stacked between two adjacent ones of the plurality of inner spacer features.

In yet another exemplary aspect, the present disclosure is directed to a semiconductor device. The semiconductor device includes a fin-shape base protruding from a semiconductor substrate, a top surface of the fin-shape base being in a (110) crystal plane, a plurality of channel members disposed over the top surface of the fin-shape base, a plurality of inner spacer features interleaving the plurality of channel members, a gate structure wrapping around each of the plurality of channel members, a source/drain feature in contact with the plurality of channel members and the plurality of inner spacer features, a top surface of the source/drain feature being in a (110) crystal plane, and a dielectric film directly under the source/drain feature and above the top surface of the fin-shape base. In some embodiments, the semiconductor device also includes an undoped epitaxial layer directly under the dielectric film and above the top surface of the fin-shape base, a top surface of the undoped epitaxial layer being in a (110) crystal plane. In some embodiments, the fin-shape base includes a semiconductor layer disposed on a top portion of the semiconductor substrate, the top portion of the semiconductor substrate having a top surface in a (100) crystal plane. In some embodiments, the source/drain feature is doped with a p-type dopant.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
an isolation feature over a semiconductor substrate;
first and second fin-shape bases protruding from the semiconductor substrate and through the isolation feature, a top surface of the first fin-shape base having a (100) crystal plane, the second fin-shape base having a bottom portion and a top portion, a top surface of the bottom portion of the second fin-shape base having a (100) crystal plane, a top surface of the second fin-shape base having a (110) crystal plane;
a plurality of first nanostructures vertically stacked above the top surface of the first fin-shape base;
a plurality of second nanostructures vertically stacked above the top surface of the second fin-shape base;
a first gate structure wrapping around at least one of the first nanostructures;
a second gate structure wrapping around at least one of the second nanostructures, the first and second gate structures including a gate dielectric layer and a gate electrode over the gate dielectric layer;
gate spacers extending along sidewalls of the first and second gate structures, a dielectric constant of the gate dielectric layer being greater than a dielectric constant of the gate spacers;
a first source/drain feature abutting the first nanostructures, a top surface of the first source/drain feature having a (100) crystal plane;
a second source/drain feature abutting the second nanostructures, a top surface of the second source/drain feature having a (110) crystal plane;
a first base epitaxial feature under the first source/drain feature, a top surface of the first base epitaxial feature having a (100) crystal plane; and
a second base epitaxial feature under the second source/drain feature, a top surface of the second base epitaxial feature having a (110) crystal plane.

2. The semiconductor device of claim 1, wherein the top surface of the first fin-shape base and the top surface of the second fin-shape base are coplanar.

3. The semiconductor device of claim 1, wherein the top surface of the bottom portion of the second fin-shape base is above a top surface of the isolation feature.

4. The semiconductor device of claim 1, wherein a top surface of a topmost one of the first nanostructures has a (100) crystal plane, and a top surface of a topmost one of the second nanostructures has a (110) crystal plane.

5. The semiconductor device of claim 1, wherein the second fin-shape base also includes a buried silicon oxide layer (BOX) disposed on the top surface of the bottom portion of the second fin-shape base and under the top portion of the second fin-shape base.

6. The semiconductor device of claim 1, wherein a vertical distance measured from the top surface of the bottom portion of the second fin-shape base to the top surface of the second fin-shape base ranges from about 30 nm to about 100 nm.

7. The semiconductor device of claim 1, further comprising:
a first dielectric film vertically stacked between the first base epitaxial feature and the first source/drain feature; and
a second dielectric film vertically stacked between the second base epitaxial feature and the second source/drain feature.

8. The semiconductor device of claim 1, further comprising:
first inner spacers interposing the first source/drain feature and the first gate structure; and
second inner spacers interposing the second source/drain feature and the second gate structure.

9. The semiconductor device of claim 8, wherein end portions of the first nanostructures are sandwiched between adjacent ones of the first inner spacers, and end portions of the second nanostructures are withdrawn from being sandwiched between adjacent ones of the second inner spacers.

10. The semiconductor device of claim 1, wherein the first nanostructures, the first gate structure, the first source/drain feature are portions of an n-type transistor, and wherein the second nanostructures, the second gate structure, the second source/drain feature are portions of a p-type transistor.

11. A semiconductor device, comprising:
a fin-shape base protruding from a semiconductor substrate, a top surface of the semiconductor substrate being in a (100) crystal plane, a top surface of the fin-shape base being in a (110) crystal plane;
a plurality of channel members disposed over the top surface of the fin-shape base;
a gate structure wrapping around at least one of channel members;
a gate spacer extending along a sidewall of the gate structure;
a source/drain feature abutting the channel members, a top surface of the source/drain feature being in a (110) crystal plane; and
a dopant-free epitaxial feature under the source/drain feature, a top surface of the dopant-free epitaxial feature being in a (110) crystal plane.

12. The semiconductor device of claim 11, further comprising:
a dielectric film vertically stacked between the dopant-free epitaxial feature and the source/drain feature, wherein a top surface of the dielectric film is above the top surface of the fin-shape base.

13. The semiconductor device of claim 11, wherein the fin-shape base includes a first crystalline portion and a second crystalline portion over the first crystalline portion, wherein a top surface of the first crystalline portion is in a (100) crystal plane.

14. The semiconductor device of claim 11, wherein the source/drain feature is doped with a p-type dopant.

15. The semiconductor device of claim 11, further comprising:
inner spacers interposing the source/drain feature and the gate structure, wherein a sidewall of the source/drain feature has protruding portions vertically stacked between adjacent ones of the inner spacers.

16. A method, comprising:
towards a top surface of a first semiconductor substrate, bonding a second semiconductor substrate, the first semiconductor substrate having a first crystalline orientation, the second semiconductor substrate having a second crystalline orientation that is different from the first crystalline orientation;
removing the second semiconductor substrate from a first region to expose the first semiconductor substrate in the first region, while the second semiconductor substrate covering the first semiconductor substrate in a second region;
thickening the first semiconductor substrate in the first region;
planarizing the first semiconductor substrate and the second semiconductor substrate;
forming a stack over the first semiconductor substrate in the first region and over the second semiconductor substrate in the second region, the stack comprising a plurality of channel layers interleaved by a plurality of sacrificial layers;
patterning the stack and the first semiconductor substrate to form a first fin-shape structure in the first region;
patterning the stack, the second semiconductor substrate, and the first semiconductor substrate to form a second fin-shape structure in the second region;
forming a first dummy gate stack over a channel region of the first fin-shape structure and a second dummy gate stack over a channel region of the second fin-shape structure;
recessing a source/drain region of the first fin-shape structure to form a first source/drain trench in the first region and a source/drain region of the second fin-shape structure to form a second source/drain trench in the second region;
epitaxially growing a first epitaxial feature in the first source/drain trench and a second epitaxial feature in the second source/drain trench, the first epitaxial feature having the first crystalline orientation, the second epitaxial feature having the second crystalline orientation;
removing the first and second dummy gate stacks;
removing the sacrificial layers from the first and second regions to release the channel layers as channel members; and
forming a first gate structure and a second gate structure wrapping around the channel members in the first and second regions, respectively.

17. The method of claim 16, further comprising:
partially recessing the sacrificial layers to form inner spacer recesses in the first and second regions;
forming inner spacer features in the inner spacer recesses in the first and second regions; and
after the inner spacer features, laterally recessing the channel layers in the second region, while the channel layers in the first region remaining intact.

18. The method of claim 16, further comprising:
prior to the epitaxially growing of the first and second epitaxial features, epitaxially growing a first base epitaxial layer in the first source/drain trench and a second base epitaxial layer in the second source/drain trench, the first base epitaxial layer having the first crystalline orientation, the second base epitaxial layer having the second crystalline orientation.

19. The method of claim 18, further comprising:
after the epitaxially growing of the first and second base epitaxial layers and prior to the epitaxially growing of the first and second epitaxial features, forming a first dielectric film covering the first base epitaxial layer and a second dielectric film covering the second base epitaxial layer.

20. The method of claim 16, further comprising:
prior to the removing of the second semiconductor substrate from the first region, thinning the second semiconductor substrate in both the first and second regions.
